(19) United States
(12) Patent Application Publication
(10) Pub. No.: US 2016/0241204 A1
(43) Pub. Date: Aug. 18, 2016

(54) IMPEDANCE TRANSFORMER FOR ANTENNA MULTIPLEXING

(71) Applicant: GainSpan Corporation, San Jose, CA (US)

(72) Inventors: Thai NGUYEN, San Jose, CA (US); Lewis E. ADAMS, III, San Jose, CA (US)

(21) Appl. No.: 14/687,626

(22) Filed: Apr. 15, 2015

Related U.S. Application Data
(60) Provisional application No. 62/117,669, filed on Feb. 18, 2015.

(51) Int. Cl. H03H 7/38

(52) U.S. Cl. CPC H03F 1/56; H03F 3/19; H03F 3/21; H03F 2200/451; H03F 2200/294

(57) ABSTRACT

A system for matching impedance of antennas includes a first switch for receiving signals that includes a first power amplifier, a first low noise amplifier coupled to the first power amplifier and a first antenna coupled to both the first power amplifier and the first low noise amplifier. The first switch is configured to match the impedance of the first antenna with the impedance of the first low noise amplifier. The system also includes a second switch for transmitting signals and coupled to the first antenna.

### CROSS-REFERENCE TO RELATED APPLICATION

This application claims the benefit under 35 U.S.C. §119(e) to U.S. Provisional Patent Application No. 62/117,669 entitled “IMPEDANCE TRANSFORMER FOR ANTENNA MULTIPLEXING,” filed on Feb. 19, 2015, the disclosure of which is expressly incorporated by reference herein in its entirety.

### TECHNICAL FIELD

The present disclosure generally relates to integrated circuits. More specifically, the present disclosure relates to an impedance transformer for an integrated on-chip T/R switch.

### BACKGROUND

The rapid growth of the wireless local area network (WLAN) market has brought about new circuit techniques that integrate components such as transmit/receive (T/R) switches or impedance transformers onto a monolithic CMOS integrated circuit to alleviate manufacturing costs. The popularity of multiple-input multiple-output (MIMO) technologies has further heightened the appeal of using these components because any external front-end component must be multiplied by the number of radio frequency (RF) chains.

While solutions exist to integrate a low noise amplifier (LNA) and a T/R switch with a power amplifier (PA) that runs at a lower power, the requirements to achieve a higher output power on a CMOS system on chip (SoC) often directly contradict the conditions for achieving a high sensitivity LNA. That is, a LNA and T/R switch topology integrated with a PA topology usually compromises the performance and/or reliability of the LNA. Furthermore, the impedance values for all components may take up excessive additional silicon area.

An integrated T/R switch or impedance transformer should be designed to support the high output power requirements of the PA, while adding minimal insertion loss for both the receive and transmit paths. A PA with high power requires a low load impedance, a high voltage supply, and a large supply current. On the other hand, a CMOS LNA requires a high optimal impedance for a minimum noise figure.

### SUMMARY

In one aspect, a system for matching impedance of antennas is provided. The system includes a first switch for receiving signals that includes a first power amplifier, a first low noise amplifier coupled to the first power amplifier and a first antenna coupled to both the first power amplifier and the first low noise amplifier. The first switch is configured to match the impedance of the first antenna with the impedance of the first low noise amplifier. The system may also include a second switch for transmitting signals and coupled to the first antenna. The second switch may include include a second power amplifier, a second low noise amplifier coupled to the second power amplifier and a second antenna coupled to both the second power amplifier and the second low noise amplifier. The second switch is also configured to match the impedance of the second antenna with the impedance of the second power amplifier.

Another aspect discloses a method. The method includes receiving signals with a first switch having a first antenna, a first power amplifier and a first low noise amplifier. The method also includes matching the impedance of the first antenna with the first low noise amplifier. In one configuration, the first antenna is coupled to a second switch. The method may further include transmitting signals with the second switch having a second antenna, a second power amplifier and a second low noise amplifier. The method also includes matching the impedance of the second antenna with the second power amplifier.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a typical transmit/receive (T/R) switch.

FIG. 2 is a schematic diagram of a traditional T/R switch circuit.

FIGS. 3A-3D are schematic diagrams of different configurations of the T/R switch circuit shown in FIG. 2.

FIG. 4 is a schematic diagram of a T/R switch design according to an aspect of the present disclosure.

FIG. 5A is a schematic diagram of an impedance inverter mechanism according to an aspect of the present disclosure.

FIG. 5B is a schematic diagram of an impedance inverter circuit according to an aspect of the present disclosure.

FIG. 6 is a schematic diagram of a combined T/R switch according to another aspect of the present disclosure.

FIG. 7 is a schematic diagram of combined T/R switches according to an aspect of the present disclosure.

FIG. 8A is a schematic diagram showing the circuit structure of a T/R switch according to an aspect of the present disclosure.

FIG. 8B is a schematic diagram showing a transmission configuration for biasing, according to an aspect of the present disclosure.

FIG. 8C is a schematic diagram showing a receiving configuration for biasing, according to an aspect of the present disclosure.

FIG. 9 is a process flow diagram illustrating a method for using an T/R switch according to an aspect of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Overview

The present disclosure describes impedance transformers or transmit/receive (T/R) switches. T/R switches may be coupled to other components such as power amplifiers (PAs), low noise amplifiers (LNAs) or antennas. However, when integrating LNAs with PAs on a T/R switch, there are properties that must be balanced. For example, the high power output capacity of the PA may compromise the sensitivity, performance and reliability of the LNA. Furthermore, the impedance values for all components may take up excessive additional silicon area and should be minimized.

A T/R switch integrated with a PA should be designed to support the high output power requirements of the PA, while adding minimal insertion loss for both the receive and transmit paths. A PA with high output power requires a low load impedance, a high voltage supply, and a large supply current. On the other hand, a T/R switch integrated with a CMOS implemented LNA requires a high optimal impedance for a minimum noise figure.

Typical T/R switches may be single pole double throw (SPDT). The number of poles is the number of separate circuits controlled by a switch. The number of throws is the number of separate positions that the switch can adopt. An example of a SPDT switch is a simple changeover switch where a common terminal is coupled to a first terminal or a second terminal.

In one implementation, more than one T/R switch is combined into a combined T/R switch that has improved properties in terms of a high output impedance for the PA regardless of whether the PA is on or off, and a LNA switch for low input impedance at LNA power down times.

Typical T/R Switch

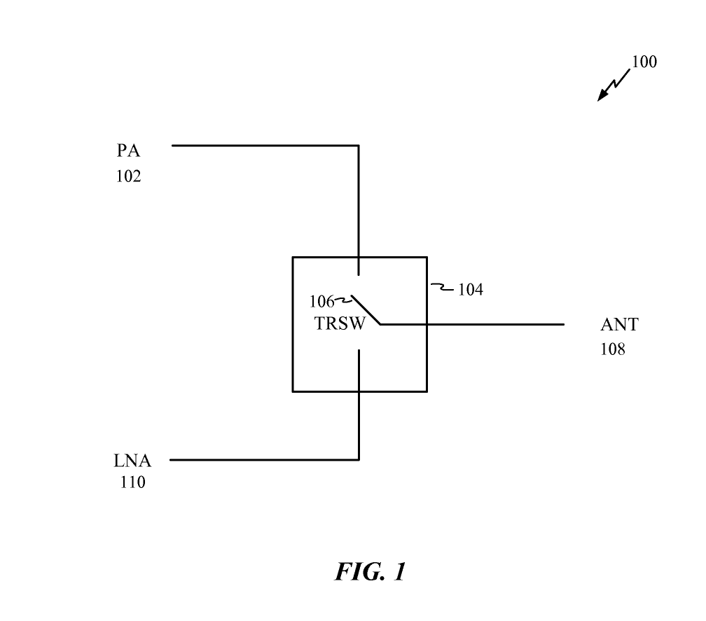

FIG. 1 is a schematic diagram 100 of a typical transmit/receive (T/R) switch 104. The T/R switch 104 is coupled to a power amplifier (PA) 102, a low noise amplifier (LNA) 110 and an antenna (ANT) 108. The T/R switch 104 includes a switch 106. The switch 106 is always coupled to the ANT 108 and alternates between the PA 102 and the LNA 110. In this respect, the switch 106 is a single pole double throw (SPDT) switch.

The T/R switch 104 may have a transmit path from the PA 102 to the ANT 108, when the switch 106 is coupled to the PA 102 and the PA 102 is coupled to the ANT 108. The T/R switch 104 may have a receive path from the LNA 110 to the ANT 108, when the switch 106 is coupled to the LNA 110 and the LNA 110 is coupled to the ANT 108. The insertion loss values for both the transmit and receive paths are also high because the PA 102 has been integrated into the T/R switch 104.

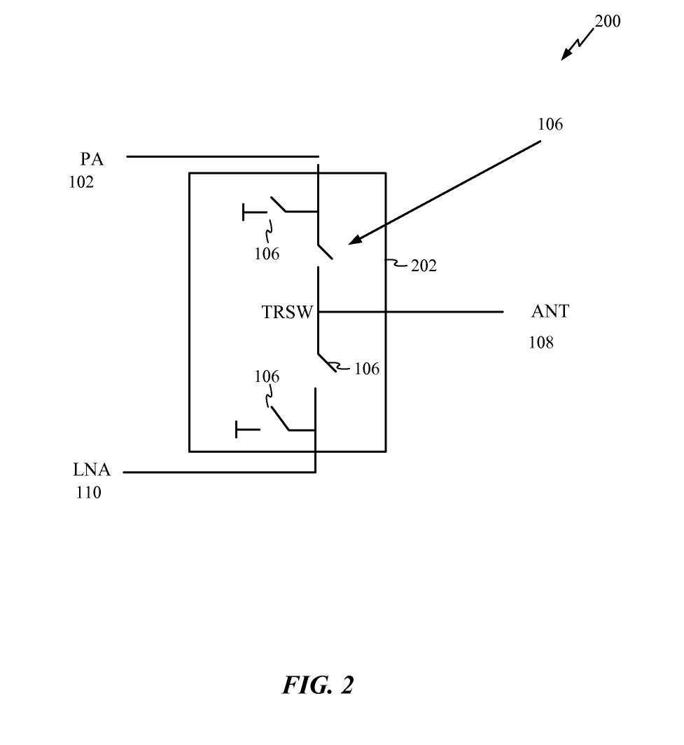

FIG. 2 is a schematic diagram 200 of a traditional T/R switch circuit 202. The traditional T/R switch circuit 202 is similar to the T/R switch 104 of FIG. 1, except there are multiple switches 106. These multiple switches 106 lead to linearity issues and reliability issues. These multiple switches 106 also lead to turn on/turn off issues when it takes too much resistance for turning on or turning off the transmit or receive paths. The traditional T/R switch circuit 202 is one traditional circuit used to realized the SPDT T/R switch. A design challenge is building a serial switch where the PA 102 is in serial with all other components.

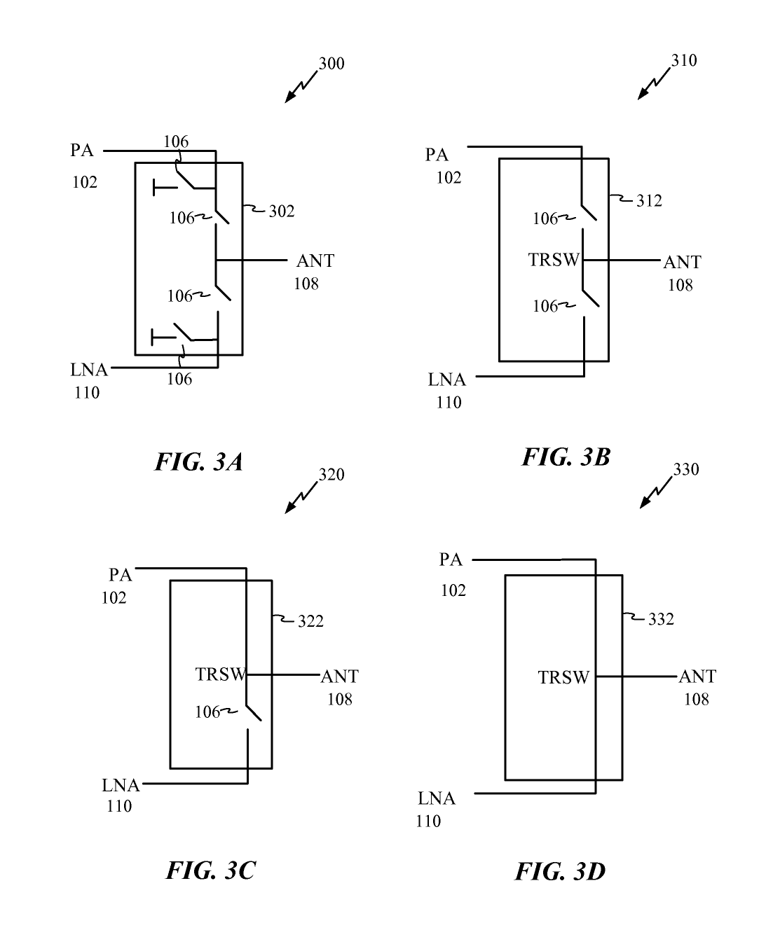

FIGS. 3A-3D are schematic diagrams of different configurations of the T/R switch circuit shown in FIG. 2. Diagram 300 shows a T/R switch circuit 302 that is identical to the T/R switch circuit 202 of FIG. 2. Diagram 310 shows a T/R switch circuit 312 with two switches 106. Diagram 320 shows a T/R switch circuit 322 with just one switch 106. Diagram 330 shows a T/R switch circuit 332 with no switches.

The T/R switch circuits shown in diagrams 300, 310, 320 and 330 take the advantage of a high PA 102 or LNA 110 impedance when the power is down. The constraints for all the T/R switch circuits shown in diagrams 300, 310, 320 and 330 is that the PA 102 and LNA 110 use the same power supply, and the PA 102 and the LNA 110 have the same load or source impedance (100Ω).

For all the diagrams 300, 310, 320 and 330, the transmission on resistance and the transmission off resistance for the PA 102 may be 2 Kn. Also for all the diagrams 300, 310, 320 and 330, the receive on resistance for the LNA 110 may be 100Ω and the receive off resistance for the LNA 110 may be a very high impedance.

T/R Switch of Present Disclosure

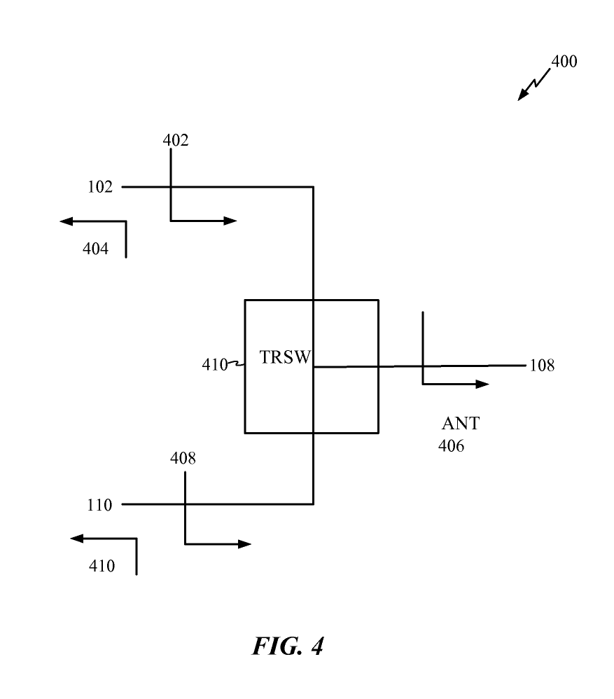

FIG. 4 is a schematic diagram 400 of a T/R switch 410 design according to an aspect of the present disclosure. The impedance matching values of the PA 102 and the LNA 110 are varied in order to produce desired results for this design. Because the power supply values for the PA 102 (e.g., 3.3V) and the LNA 110 (e.g., 1.2V) may be different, the PA 102 (a PA matching impedance 402 of 50Ω) and the LNA 110 (a LNA matching impedance 408 of 100Ω) may be used. As a result, the ANT matching impedance 406 may have to be a high value for the ANT 108.

For schematic diagram 400, the transmission on resistance and the transmission off resistance for the PA 102 may be 2 K. Also for schematic diagram 400, the receive on resistance for the LNA 110 may be 100Ω and the receive off resistance for the LNA 110 may be a very high impedance.

Impedance Inverter Circuits

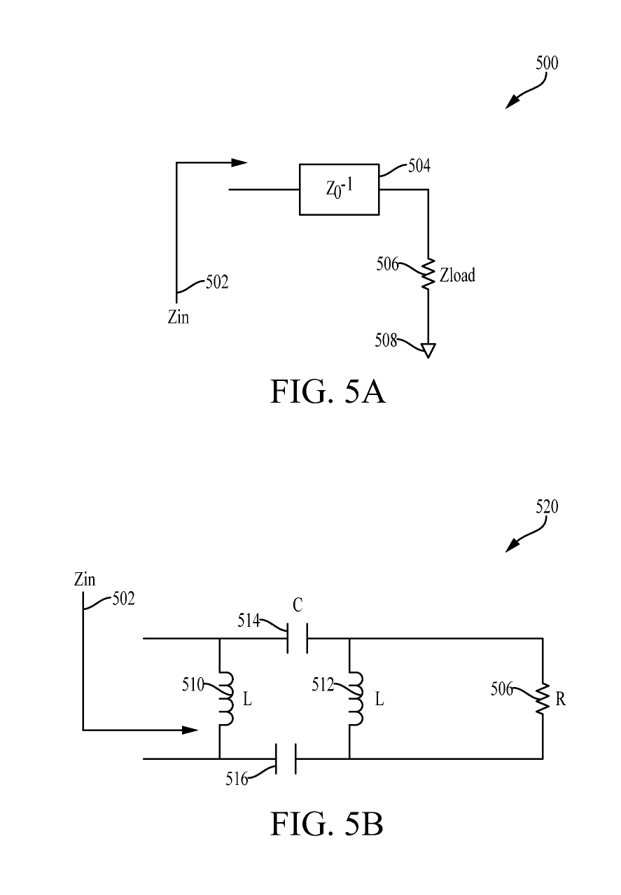

FIG. 5A is a schematic diagram 500 of an impedance inverter mechanism according to an aspect of the present disclosure. An input impedance 502 is fed into an impedance inverter 504, resulting in a load impedance 506, which is coupled to ground 508. If the input impedance 502 is high, then the load impedance 506 is low, and vice versa, if the input impedance 502 is low, then the load impedance 506 is high. The relationship between the input impedance 502 (Zᵢₙ) and the load impedance 506 (Z_{load}) may be expressed by the formula: Zᵢₙ=(Zₒ)²/Z_{load}, where Zₒ is an initial impedance value. When Zₒ=Z_{load}, then Zᵢₙ=Z_{load}.

FIG. 5B is a schematic diagram 520 of an impedance inverter circuit according to an aspect of the present disclosure. The input impedance 502 is instead fed into a differential circuit including a first capacitor 514, a second capacitor 516, a first inductor 510 and a second inductor 512. The output of the differential circuit is coupled to the load impedance 506. This is just one example of how an impedance inverter circuit may be implemented.

Combined T/R Switch Circuits of Present Disclosure

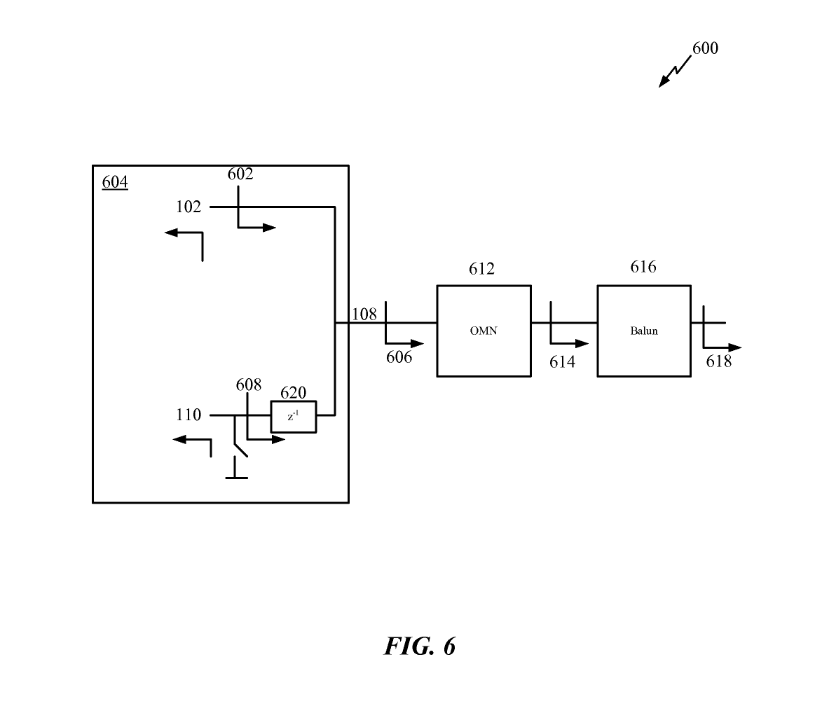

FIG. 6 is a schematic diagram 600 of a combined T/R switch according to another aspect of the present disclosure. Because power supply values for the PA 102 (e.g., 3.3V) and the LNA 110 (e.g., 1.2V) may be different, the PA 102 (a PA matching impedance 602 of 50Ω) and the LNA 110 (a LNA matching impedance 608 of 100Ω) may be used. The LNA 110 may also be coupled to an impedance inverter 620. The ANT matching impedance 606 may be 50Ω in order to properly balance out the impedance of the rest of the combined T/R switch 604. Afterwards, coupled to the ANT 108 may be a second T/R switch (OMN) 612, having a second T/R switch matching impedance 614 of 100Ω. Coupled to the second T/R switch (OMN) 612 is a third T/R switch (Balun) 616, having a third T/R switch matching impedance 618 of son. The Balun may signify the ratio of sizing of devices (e.g., 2:1) within the third T/R switch 616 so as to ensure balanced impedance overall.

The combined T/R switch 604 may be composed of: the impedance inverter 620, the PA 102 high output impedance no matter if the PA 102 is on or off, and a LNA 110 switch for low input impedance during LNA 110 power down.

For combined T/R switch 604, the transmission on resistance and the transmission off resistance for the PA 102 may be 2 KΩ. Also for combined T/R switch 604, the receive on resistance for the LNA 110 may be 100Ω and the receive off resistance for the LNA 110 may be a very high impedance.

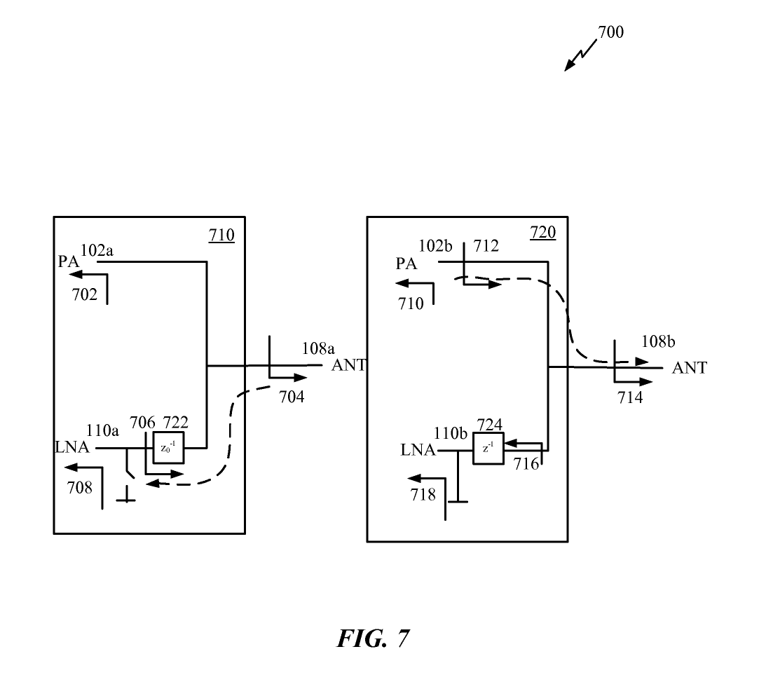

FIG. 7 is a schematic diagram 700 of combined T/R switches 710 and 720 according to an aspect of the present disclosure.

The receiver T/R switch 710 includes a first PA 102a, a first PA receive off resistance 702, a first LNA 110a, a first LNA receive on resistance 708, a first input impedance 706, a first impedance inverter 722 and a first antenna matching impedance 704 of the first antenna 108a.

In one implementation, the first PA receive off resistance is 2 KR the first LNA receive on resistance 708 is 100Ω, the first input impedance 706 is 100Ω when Zₒ is equal to 75Ω, and the first antenna matching impedance 704 is 50Ω.

The transmission T/R switch 720 includes a second PA 102b, a second PA receive on resistance 708, a second PA matching impedance 712, a second LNA 110b, a second LNA transmission off impedance 718, a second impedance inverter 724, a second input impedance 716, and a second antenna matching impedance 714 of the second antenna 108b.

In one implementation, the second PA receive on resistance 708 is 2 KR the second PA matching impedance 712 is 50Ω, the second input impedance 716 is a high impedance value when the LNA 110b switch is on, the second LNA transmission off impedance 718 is a high impedance value, and the second antenna matching impedance 714 is 50Ω.

Circuit Structure and Implementation of T/R Switch

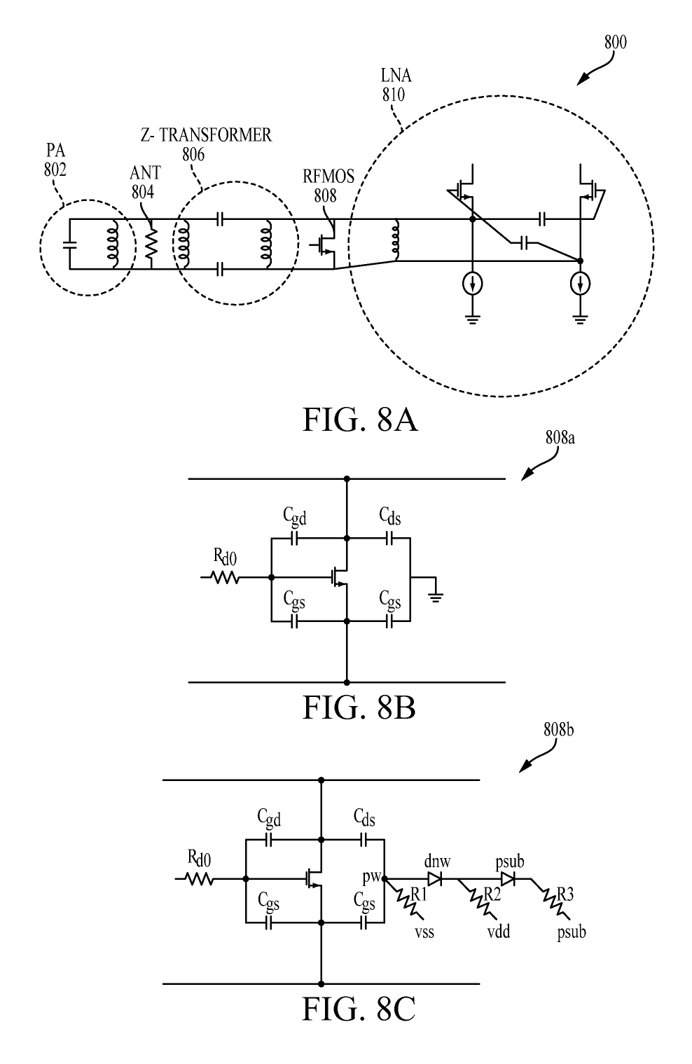

FIG. 8A is a schematic diagram showing the circuit structure of a T/R switch 800 according to an aspect of the present disclosure. The T/R switch 800 includes a power amplifier (PA) 802, an antenna (ANT) 804, an impedance transformer 806, a biasing circuitry 808, and a low noise amplifier (LNA) 810. The impedance transformer 806 may be used to match the impedance of the overall T/R switch 800, or match the impedance of the PA 802 and the LNA 810. The biasing circuitry 808 may be implemented in Metal Oxide Semiconductor (MOS) transistors configured for radio frequency (RF) applications. As a result, the MOS transistors used in the biasing circuitry 808 may only be applicable for a certain range of frequencies in the RF spectrum, for example.

FIG. 8B is a schematic diagram showing a transmission configuration for biasing, according to an aspect of the present disclosure. A transmission mode 808a has the LNA 810 power down, with the biasing circuitry 808 switching on. In one implementation, the transmission mode 808a has the Vd=Vs=0V.

FIG. 8C is a schematic diagram showing a receiving configuration for biasing, according to an aspect of the present disclosure. A receiving mode 808b has the LNA 810 power up, with the biasing circuitry 808 switching off. In one implementation, the receiving mode 808b has the Vd=Vs=200 mV.

Note that in FIG. 8C, the positioning of the components Rd0, Cgd, Cds, the two Cgs and the middle transistor are identical. However, in FIG. 8C, there are additional resistors (e.g., R1 coupled to Vss, R2 coupled to Vdd, R3 coupled to psub) and diodes (dnw and psub) used to match the impedance in the receiving mode.

Process Flow

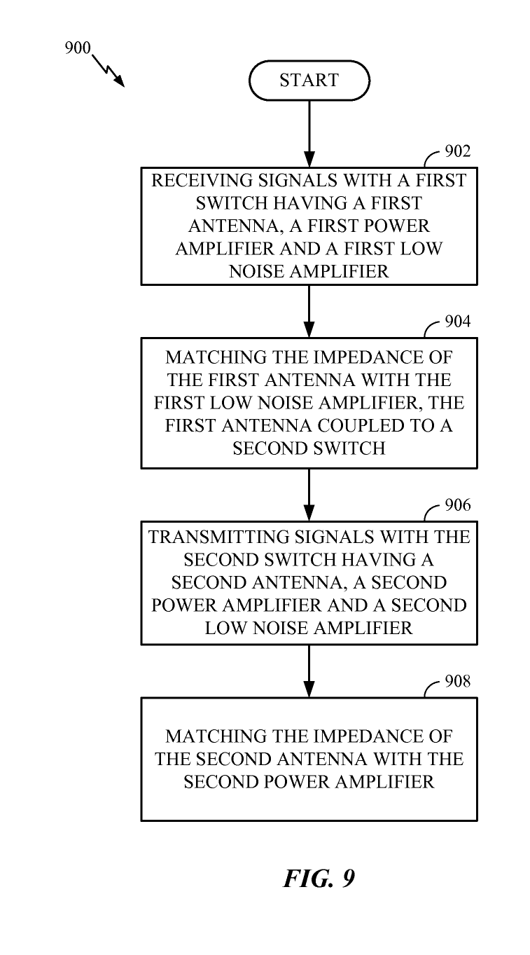

FIG. 9 is a process flow diagram illustrating a method for using an T/R switch according to an aspect of the present disclosure. In block 902, receiving is performed with a first switch having a first antenna, a first power amplifier and a first low noise amplifier. In block 904, the impedance of the first antenna is matched with the first low noise amplifier, the first antenna coupled to a second switch. In block 906, transmitting is performed with the second switch having a second antenna, a second power amplifier and a second low noise amplifier. In block 908, the impedance of the second antenna is matched with the second power amplifier.

Implementation Alternatives

For a firmware and/or software implementation, the methodologies may be implemented with modules (e.g., procedures, functions, and so on) that perform the functions described herein. A machine-readable tangible medium including one or more instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

The foregoing description of one or more embodiments or aspects of the present disclosure has been presented for the purposes of illustration and description. It is not intended to be exhaustive or to limit the disclosure or the invention to the precise form disclosed. Many modifications and variations are possible in light of the above teaching. Although the present disclosure and invention has been described in connection with certain embodiments, it is to be understood that modifications and variations may be utilized without departing from the principles and scope of the disclosure or invention, as those skilled in the art will readily understand. Accordingly, such modifications would be practiced within the scope of the disclosure and invention, and within the scope of the following claims or within the full range of equivalents of the claims.

Further, the attached claims are presented merely as one aspect of the present invention. No disclaimer is intended, expressed, or implied for any claim scope of the present invention through the inclusion of this or any other claim language that is presented herein or may be presented in the future. Any disclaimers, expressed or implied, made during prosecution of the present application regarding the claims presented, changes made to the claims for clarification, or other changes made during prosecution, are hereby expressly disclaimed for at least the reason of recapturing any potential disclaimed claim scope affected by presentation of specific claim language during prosecution of this and any related applications. Applicant reserves the right to file broader claims, narrower claims, or claims of different scope or subject matter, in one or more continuation or divisional applications in accordance within the full breadth of the present disclosure, and the full range of doctrine of equivalents of the present disclosure, as recited in this specification.

What is claimed is:

1. A system for matching impedance of antennas, comprising:
a first switch for receiving signals comprising a first power amplifier, a first low noise amplifier coupled to the first power amplifier and a first antenna coupled to both the first power amplifier and the first low noise amplifier, the first switch configured to match a first antenna impedance with a first low noise amplifier impedance; and
a second switch for transmitting signals and coupled to the first antenna, the second switch comprising a second power amplifier, a second low noise amplifier coupled to the second power amplifier and a second antenna coupled to both the second power amplifier and the second low noise amplifier, the second switch configured to match a second antenna impedance with a second power amplifier impedance.

2. The system of claim 1,
the first switch further comprising a first impedance inverter having an input coupled to the first low noise amplifier and having an output coupled to the first power amplifier and the first antenna; and
the second switch further comprising a second impedance inverter having an input coupled to the second low noise amplifier and having an output coupled to the second power amplifier and the second antenna.

3. The system of claim 2, in which the first switch comprises a first sub-switch having a first end coupled to the first low noise amplifier and the first impedance inverter and a second end coupled to ground, the first sub-switch being off and there being no coupling between the first end and the second end of the first sub-switch.

4. The system of claim 2, in which impedance matching occurs in the first switch between the first low noise amplifier impedance and the first antenna impedance.

5. The system of claim 4, in which the first low noise amplifier impedance is 100Ω when an initial impedance of the first impedance inverter is 75Ω and the first antenna impedance is 50Ω.

6. The system of claim 1, in which the first switch has a receiving off resistance for the first power amplifier of 2 KΩ and a receiving on resistance for the first low noise amplifier of 100Ω.

7. The system of claim 2, in which the second switch comprises a second sub-switch having a first end coupled to the second low noise amplifier and the second impedance inverter and a second end coupled to ground, the second sub-switch being on and there being a coupling between the first end and the second end of the second sub-switch.

8. The system of claim 7, in which an input impedance looking into the second impedance inverter is a high impedance value when the second sub-switch is on.

9. The system of claim 2, in which impedance matching occurs in the second switch between the second power amplifier impedance and the second antenna impedance.

10. The system of claim 9, in which the second power amplifier impedance is 50Ω and the second antenna impedance is 50Ω.

11. The system of claim 1, in which the second switch has a transmission on resistance for the second power amplifier of 2 KΩ and a transmission off resistance for the second low noise amplifier of a high impedance value.

12. A method for matching impedance of antennas, comprising:
receiving signals with a first switch having a first antenna, a first power amplifier and a first low noise amplifier;
matching first antenna impedance with a first low noise amplifier impedance;
transmitting signals with a second switch coupled to the first antenna, the second switch having a second antenna, a second power amplifier and a second low noise amplifier; and
matching a second antenna impedance with a second power amplifier impedance.

13. The method of claim 12, further comprising:
inverting a first switch impedance with a first impedance inverter that has an input coupled to the first low noise amplifier and has an output coupled to the first power amplifier and the first antenna; and
inverting a second switch impedance with a second impedance inverter that has an input coupled to the second low noise amplifier and has an output coupled to the second power amplifier and the second antenna.

14. The method of claim 13, further comprising:
switching a first sub-switch in the first switch to an off position, the first sub-switch having a first end coupled to the first low noise amplifier and the first impedance inverter and a second end coupled to ground, there being no coupling between the first end and the second end of the first sub-switch.

15. The method of claim 13, further comprising:
switching a second sub-switch in the second switch to the on position, the second sub-switch having a first end coupled to the second low noise amplifier and the second impedance inverter and a second end coupled to ground, there being a coupling between the first end and the second end of the second sub-switch.

16. The method of claim 13, in which the first low noise amplifier impedance is 100Ω when an initial impedance of the first impedance inverter is 75Ω and the first antenna impedance is 50Ω.

17. The method of claim 12, in which the first switch has a receiving off resistance for the first power amplifier of 2 KΩ and a receiving on resistance for the first low noise amplifier of 100Ω.

18. The method of claim 15, in which an input impedance looking into the second impedance inverter is a high impedance value when the second sub-switch is on.

19. The method of claim 12, in which the second power amplifier impedance is 50Ω and the second antenna impedance is 50Ω.

20. The method of claim 12, in which the second switch has a transmission on resistance for the second power amplifier of 2 KΩ and a transmission off resistance for the second low noise amplifier of a high impedance value.
